(19) United States
(12) Patent Application Publication
(10) Pub. No.: US 2026/0162719 A1
(43) Pub. Date: Jun. 11, 2026

(54) SELF-TIMING CIRCUIT FOR SEMICONDUCTOR MEMORY DEVICES AND MEMORY DEVICE

(71) Applicant: WEEBIT NANO LTD, Hod Hasharon (IL)

(72) Inventor: Maxim Vershkov, Ramat Gan (IL)

(73) Assignee: WEEBIT NANO LTD, Hod Hasharon (IL)

(21) Appl. No.: 19/169,175

(22) Filed: Apr. 3, 2025

(30) Foreign Application Priority Data
Dec. 10, 2024 (FR) FR2413758

(51) Int. Cl. G11C 13/00

(52) U.S. Cl. CPC G11C 13/0061; G11C 13/0026; G11C 13/004

(57) ABSTRACT

A memory circuit (MEM) comprising an array (ARR) of bit cells (BC) arranged in rows of bit cells connected to a respective word line (WL) and in columns of bit cells connected to a respective one of bit lines (BL); a sense amplifier (S-Amp) circuit to be connected to the bit lines, an external clock input (In1) fed with an external clock signal (Ext-Clck) comprising external clock pulses having a first length of time, and a timing circuit (T-Cntl) to track a time taken to charge one of the bit lines and that is a second length of time, the timing circuit (T-Cntl) generating an internal clock signal (Int-Clk) comprising internal clock pulses (Int-Clck_{Pulse}) and transmitting the internal clock signal to the sense amplifier circuit (S-Amp), the internal clock pulses having a width defined as a longest one of the first and the second lengths of time.

### CROSS-REFERENCE TO RELATED APPLICATION

The present application claims priority to French Patent Application No. 2413758, filed on Dec. 10, 2024, the contents of which are hereby incorporated by reference in their entirety.

### FIELD OF THE INVENTION

The technical domain of the invention is that of Random Access Memory (RAM) cells, that each comprise an element whose state defines a bit of information that is read or written according to timed sequences of operations.

### BACKGROUND OF THE INVENTION

In a memory such as a Random Access Memory (RAM), accurate timing of operations is essential to ensure a correct workflow of writing and reading operations. The timing and propagation of various signals directly influences the speed and reliability of data writing or retrieval.

During a typical read operation, a read word line is activated, prompting the connected memory cells to deliver their stored data, or bits, in the form of voltages to respective bit lines. These data are sensed by means of sense amplifiers that are to be enabled at given timings to ensure that the voltages of the bit lines are surely detected and processed. To this end, a memory timing circuit plays a crucial role by generating timing signals that determine when the sense amplifiers should be activated.

However, real-world factors such as variations in the fabrication process and use of the memory, known as PVT variations for Process, Voltage and Temperature, introduce variations in signals propagations and charging of the word lines and the bit lines, affecting the operations of the memory, notably the read operations.

Process variations originate form the fabrications process of the memory, formed from a chip that is a part of a wafer of semiconductor material. During the processing of the wafer, inevitable variations occur depending on the location of the chip on the wafer and on the difficulty of reproducing exactly the same manufacturing parameters, especially when lower manufacturing nodes are considered. One my cite, for example, UV light wavelength, oxide thickness, mobility of electrical charge carriers, transistor channel lengths, metal thicknesses, diffusion depths and so on. Voltage variations originates from voltage drop over the power grid network within the memory, noise due to parasitic inductance, irregularities in the voltage delivered by an on-chip voltage regulator, for examples. Temperature variations may arise due to the non-uniform transistor density or switching throughout the memory.

As a consequence, components of the circuit forming the memory can be associated to respective resistances R and capacitances C, so that each component present a individual “RC characteristic”. These RC characteristics govern propagation of signals throughout the memory, for example along bit lines and word lines. Among chips originating from a same wafer, and thus having been submitted to nominally identical treatment, some chips can thus propagate signals faster than other ones. The former chips are sometimes referred to as “fast corners” while the latter are sometimes referred to as “slow corners”. Taking into account speed of propagations of the signals is a must to obtain high-performance memories, as they rely heavily on time-dependent operations.

To address the consequences of such non-controlled variations in the memory, timing circuits that are resilient to PVT variations are required. Such circuits need to be able to maintain accurate timing of operations despite environmental and operational changes. The timing circuits can be arranged to track or emulate signals in may employ dummy word line and/or dummy bit lines to generate appropriate timing signals. One may refer for example to the patent documents U.S. Pat. Nos. 6,181,626 B1, 6,646,938 B2, US 20150063046 A1, EP 0422939 B1, U.S. Pat. No. 6,388,931 or US 2008205176 A1. These circuits are largely employ to control similarly circuits originating from slow corners and from fast corners, so that differences in their effective characteristics does not impact the way to control them, which can then be applied to every memory, independently on whether it is “fast” or “slow”.

Yet, there is still a need for better and simpler control of read operations in a memory circuit, taking into account the individual characteristics of memories, even of memories sharing a same design.

### OBJECT OF THE INVENTION

In the context described above, it is proposed to enhance control over a timing pulse width employed to control latching of a sense amplifier in a memory circuit.

### SUMMARY OF THE INVENTION

To this effect, a first aspect of the invention relates to a memory circuit comprising: an array of bit cells arranged in rows of bit cells each connected to a respective word line and in columns of bit cells each connected to a respective one of bit lines, the word lines being connected to a word line driver circuit, the bit lines being connected to a multiplexer circuit; a sense amplifier circuit configured to be connected to the bit lines, an external clock input configured to be fed with an external clock signal comprising external clock pulses having a first length of time, and a timing circuit configured to track a time taken to charge one of the bit lines and that is a second length of time, the timing circuit being configured to generate an internal clock signal comprising internal clock pulses and transmit the internal clock signal to the sense amplifier circuit, the internal clock pulses having a width defined as a longest one of the first length of time and the second length of time.

Advantageously, such memory circuit allows an automatic adaptation of an internal clock signal to the variations of memories having a same design. This clock signal is employed to determining the right timing to enable the sense amplifier circuit, i.e. when the bit lines are fully charged during a read operation.

The circuit is adapted to equip memory circuits regardless of whether they are “fast corner” or “slow corner”, meaning signals propagate therein faster or slower than an typical propagation speed. Further, the circuit can be easily adapted to arrays of bit cells of arbitrary numbers of rows and columns.

Further, this circuit does not require the user to control a clock signal or to choose between different clock signals via an additional control signal and an additional circuit dedicated to this function since the circuit according to the invention automatically outputs a clock signal adapted to the circumstances.

According to further non limitative features of the first aspect of the invention, either taken alone or in any technically feasible combination:
the memory circuit can be configured to drive respective voltages of the bit lines in accordance to data stored in bit cells respectively connected to the bit lines during a read operation of the memory circuit;
the timing circuit can be configured to track the time taken to charge one of the first lines by tracking a time taken to charge a dummy bit line and that is representative of the time taken to charge the bit lines;
the memory circuit can comprise: a dummy word line ; and a dummy first line; the timing circuit comprising: a reset signal generating circuit configured to generate and send a pulse reset signal when a voltage of the dummy first line reach a given threshold; a pulse generating circuit having a first input connected to the external clock input and a second input configured to receive the pulse reset signal, the pulse generating circuit being configured (i) to generate and send a trigger signal to charge the dummy word line in response to a pulse of the external clock signal and (ii) to generate a pulse generating signal comprising a pulse beginning with the pulse of the external clock signal and ending upon reception of the pulse reset signal; and a pulse width determining circuit configured to receive (i) the external clock signal and (ii) the pulse generating signal, the selecting circuit being further configured to generate and output the internal clock signal;
the pulse width determining circuit can be configured to perform a function of a OR logical gate with the external clock signal and the pulse generating signal as inputs and the internal clock signal as output;
the memory circuit can further comprise a dummy bit line emulating circuit connected to the dummy bit line and configured to emulate an environment of one of the bit lines of the array of bit cells so that charging the dummy bit line takes substantially a same amount of time as charging the one of the bit lines;
the memory circuit can further comprise a dummy word line emulating circuit (connected to the dummy word line and configured to emulate an environment of one of the word lines of the array of bit cells so that a signal would propagate substantially identically along the dummy word line and along the one of the word lines;
the memory circuit can further comprise a delay circuit configured to delay the pulse generating signal generated by the pulse generation circuit before the pulse generating signal reaches the pulse width determining circuit; and
the memory circuit can be a resistive RAM.

The present invention extends to an embedded system including the memory circuit according to the first aspect of the invention, connected to a microprocessor.

### BRIEF DESCRIPTION OF THE DRAWINGS

Many other features and advantages of the present invention will become apparent from reading the following detailed description, when considered in conjunction with the accompanying drawings, in which:

FIG. 1 illustrates a conventional memory;

FIG. 2 illustrates the conventional memory of FIG. 1 equipped with circuits according to the invention;

FIG. 3 illustrates a block diagram of the circuits of FIG. 2 added to the memory of FIG. 1;

FIG. 4 illustrates a pulse width determining circuit;

FIG. 5 illustrates a portion of a bit line emulating circuit;

FIG. 6 illustrates a portion of a word line emulating circuit;

FIG. 7 illustrates another portion of the bit line emulating circuit;

FIG. 8 is a time chart of the functioning of the circuit of FIG. 3 in a slow corner situation;

FIG. 9 is a time chart of the functioning of the circuit of FIG. 3 in a fast corner situation; and

FIG. 10 illustrates an embedded system incorporating a resistive memory MEM.

The figures are schematic representations that, for the sake of clarity, are not drawn to scale.

### DETAILED DESCRIPTION OF A SPECIFIC EMBODIMENT OF THE INVENTION

FIG. 1 illustrates at (A) a generic architecture for a Random Access Memory (RAM) with an array of bit cells BC arranged in rows of bit cells BC each connected to a respective word line WL and in columns of bit cells BC each connected to a pair of respective lines, designated in this specific example as a first line or bit line, annotated BL, and as a second line or source line, annotated SL, the word lines WL being connected to a word line driver WL-Drv circuit, the bit lines BL and the source lines SL being connected to a multiplexer circuit SL/BL-Mux, a sense amplifier circuit S-Amp being connected to the bit lines via the multiplexer circuit SL/BL-Mux. In a memory array such as the one illustrated in FIG. 1(A), a bit line is a circuit component that is strongly driven to a desired value for reading or writing data stored in bit cells connected to it.

Set, reset and read operations can be applied to bit cells integrated in an array ARR of a resistive RAM-type memory MEM. FIG. 1(A) is representative of conventional structure of a resistive random access memory or ReRAM. Such a resistive RAM-type memory is described for example in the patent U.S. Pat. No. 11,735,260B2.

In the RAM of FIG. 1, each bit cell BC of the array ARR comprises one ReRAM resistor Var_{R} made of a pair of electrodes EL1 and EL2 sandwiching, for example, an oxide layer OL, and one selection transistor Sel_{Tr} having a source and a drain connected in series with the ReRAM resistor, as illustrated in FIG. 1(B).

An array ARR of bit cells comprises columns and rows of bit cells. Each column comprises (i) a bit line BL connected to a source and a drain of the transistor Sel_{Tr} through the ReRAM resistor Var_{R} for each of the bit cells of the column and (ii) a source line SL connected to the bit line BL through the source and the drain of the transistor SelTr and the ReRAM resistor Var_{R}. Each row of bit cells comprises a word line WL connected to the gate of the selection transistor Sel_{Tr} for each of the bit cells of the row. The bit lines BL and the source lines SL are each connected to and controlled through a column multiplexer circuit SL/BL-Mux. The word lines WL are each connected to and controlled by a row driver circuit WL-Drv.

In FIG. 1(A), each intersection between a word line WL and a bit line BL corresponds to a bit cell BC. FIG. 1(C) illustrates two adjacent bit cells BC1 and BC2 belonging to a same row and thus connected to a same word line WL.

The generic architecture illustrated at FIG. 1 does not allow, in itself, to address the issues linked to the PVT variations.

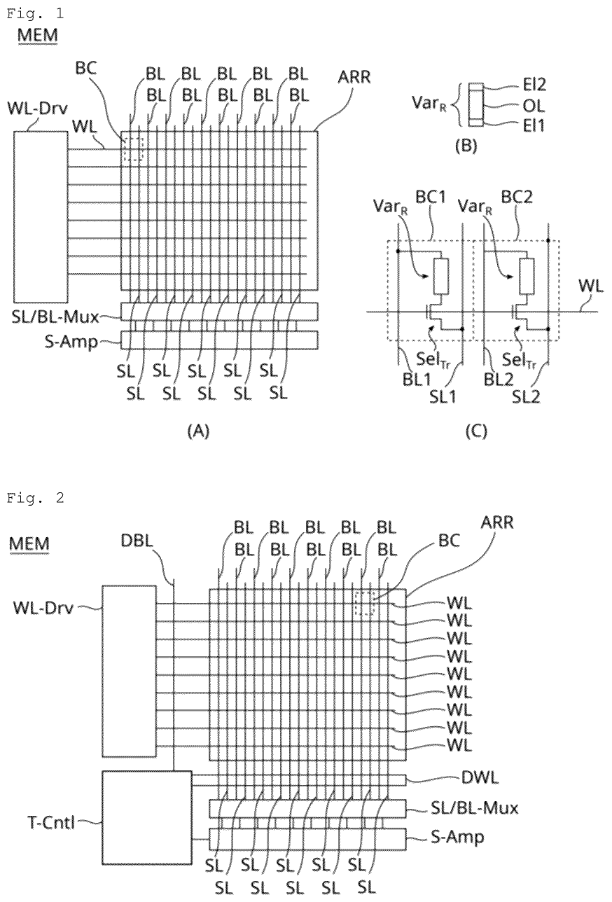

FIG. 2 illustrates the memory circuit MEM of FIG. 1 to which has been integrated a dummy bit line DBL, a dummy word line DWL and a timing circuit T-Cntl connected to the dummy bit line, the dummy word line, and the sense amplifier circuit S-Amp. The timing circuit T-Cntl is also connected to the lines of the memory necessary to the normal functioning of a circuit (clock signals transmitting lines, high or of low voltage lines, ground, control signal lines . . . ). Notably, a clock signal exterior to the timing circuit T-Cntl is identified as an external clock signal and comprise pulses of a given, constant width generated at constant intervals. Needless to say, the intervals and the width of the pulses represent respective lengths of time, and can be expressed in nanoseconds.

The dummy lines and the timing control circuit are configured to (i) to track a time taken to charge one of the bit lines and (ii) to generate an internal clock signal Int-Clk comprising internal clock pulses and to transmit the internal clock signal to the sense amplifier circuit S-Amp and other signals that are function of the clock, the internal clock pulses having a width defined as a longest one between the widths of the pulses of the external clock signal and the time it takes to charge the one of the bit lines.

Indeed, due to the PVT variations, the time required to charge the bit lines can vary from memory to memory, hence the necessity to evaluate the time effectively required to charge the bit lines and thus to perform surely a read operation. Notably, if the sense amplifier circuit is operated while the bit lines are not yet completely charged, there is a risk of inadequate reading of the content of the memory. Conversely, if the clock signal is slowed down to prevent the occurrence of incomplete charging of the bit lines, then the memory reading will be slower than necessary in many cases.

The timing control circuit solves this issue by lengthening the time of the read operation only when necessary, by lengthening pulses of an internal clock signal when the pulses of the external clock line are too short to allow a complete charging the bit lines, as assessed by the tracking of the time effectively required to charge a bit line. In this embodiment, the tracking is operated on the dummy bit line DBL, that is not connected to bit cells of the array of bit cells of the memory. This dummy bit lines is charged by means of the dummy word line DWL, that is not connected to bit cells of the array of bit cells of the memory. That is, the dummy bit line and the dummy word line are operated independently of the bit cells, except that their operation depends on the external clock signal and on voltages feeding the array of bit cells and the circuits connected thereto.

The dummy bit line and the dummy word line preferably behave similarly to the bit lines and the word lines of the array of bit cells with regard to the propagation of signals along these lines. To the end, the environments of the dummy lines are respectively arranged to this end: a bit line emulating circuit Emul.BL is preferably connected to the dummy bit line DBL. Similarly, a word line emulating circuit Emul.WL is preferably connected to the dummy wordline DWL. More specifically, these emulating circuits can reproduce the electrical capacitances that are connected to any circuit in any real implementation of this circuit, and represent, for example, parasitic capacitances that are to be charged when the bit lines and the word lines are to be charged.

Thus, the word line emulating circuit Emul.WL and the word line emulating circuit Emul.WL emulate the capacitances connected to a bit line and a word line of the array of bit cells, respectively. The capacitances depend on the exact characteristics (actual dimensions, thicknesses, geometries etc. . . . ) of the components connected to the bit line, such as connection lines and transistors. These capacitances may vary from one memory to another due to slight variations occurring during the fabrication processes, even if their design is strictly the same.

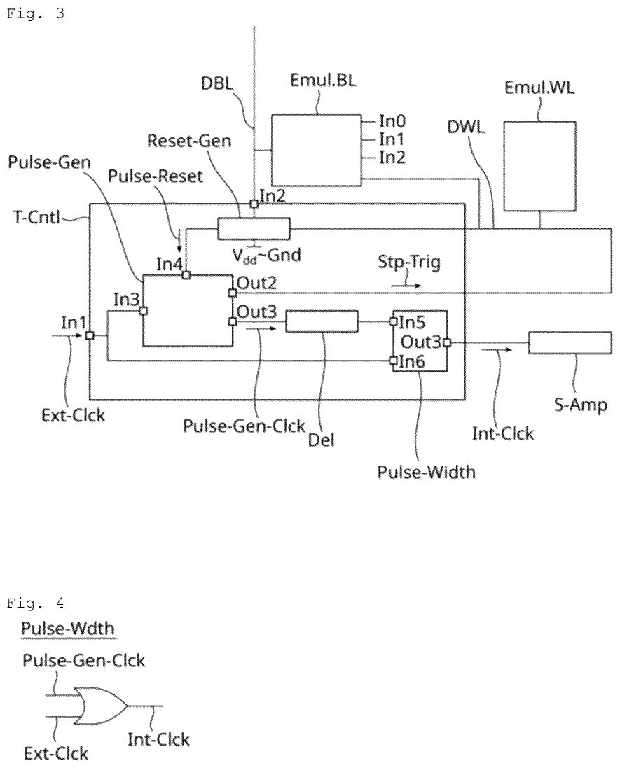

FIG. 3 illustrates the time control circuit T-Cntl, as well as the dummy bit line DBL, the dummy word line DWL, the sense amplifier circuit S-Amp (all circuits that are function of the clock), the bit line emulating circuit Emul.BL and the word line emulating circuit Emul.WL.

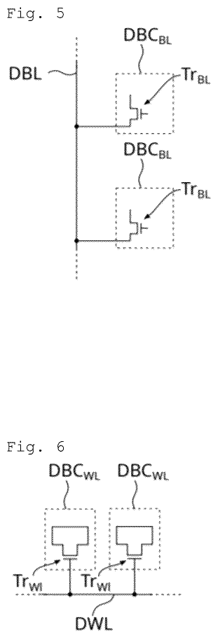

The bit line emulating circuit can comprises dummy bit cells DBC_{BL} as illustrated by FIG. 5. The dummy bit cells DBC_{BL} preferably match in number the bit cells BC connected to one of the bit lines BL in the array ARR and are preferably connected along the dummy bit lines DBL to match the connections of the bit cells BC to the bit lines BL. The dummy bit cells DBC_{BL} can each comprise a transistor Tr_{BL}, the transistors Tr_{BL} being connected to the dummy bit line DBL through one of their source and their drain so as to emulate the electrical environment of a bit line BL of the array ARR. The gates and the others of the source and the drain can be connected to ground. In this way, the capacitance effectively connected to any given one of the bit lines can be closely approached and an environment emulating, for the dummy bit line, the environment of the bit lines is reproduced.

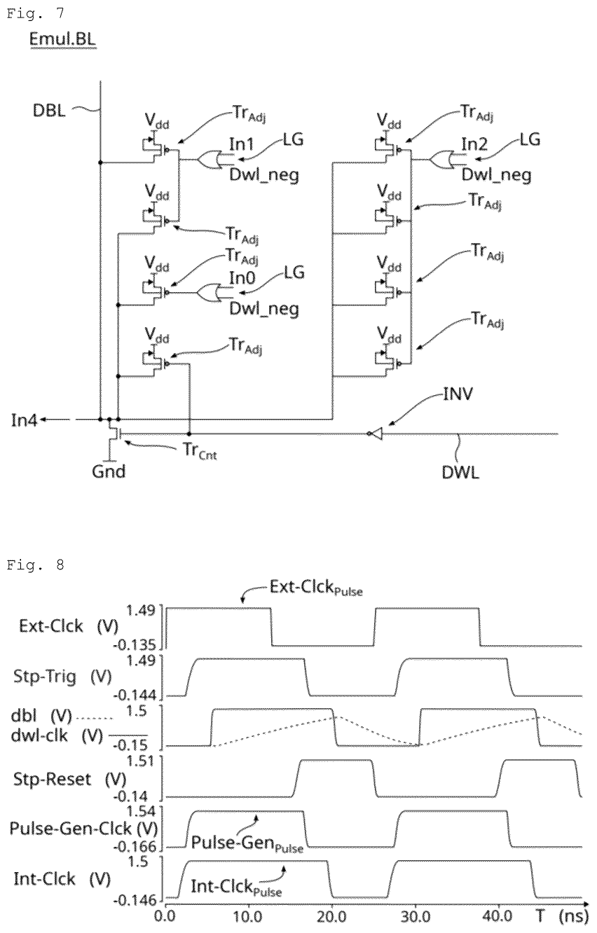

In addition, as illustrated by FIG. 7, the dummy bit line emulating circuit may optionally comprise pmos transistors Tr_{Adj} arranged to connect selectively the dummy bit line DBL to a voltage Vdd. As illustrated, the dummy bit line DBL may be connected to one of a source and a drain of each of the transistors Tr_{Adj}, and the body and the other of the source and the drain of each of the transistors Tr_{Adj} may be connected to a line at the voltage Vdd. All or part of the transistors Tr_{Adj} can be controlled by a user, in this example by means of three entries In1, In2 and In3 entered into respective control logic gates LG (in this example, OR logic gate). More generally, n entries when n is a natural number could be used, depending on the number of transistors Tr_{Adj} to control. The circuit of FIG. 7 comprises a transistor Tr_{Adj} having a gate connected to the dummy word line DWL through an inverter INV so as to provide a baseline capacitance to the dummy bit line DBL. A second entry Dwl_neg of each of the control logic gates LG is connected to the dummy word line (not represented on the figure), through the inverter INV in this example. Outputs of the control logic gates are connected to the gates of the transistors Tr_{Adj}. The total amount of capacitance effectively connected to the dummy bit line can thus be controlled, which allows to adjust a rising delay of the bit lines for any given memory and make up for the variations between memories, even if they have the same design.

Similarly to the bit line emulating circuit, the word line emulating circuit may comprise dummy bit cells DBC_{WL}, as illustrated by FIG. 6. The dummy bit cells DBC_{WL} are preferably in number matching the number of bit cells BC connected to a word line WL in the array ARR and are preferably connected along the dummy word lines DWL to match the connections of the bit cells BC to the word lines WL. The dummy bit cells DBC_{WL} can each comprise a transistor Tr_{WL}, the transistors Tr_{WL} are connected to the dummy word line DWL through their gates so as to emulate the electrical environment of a word line WL of the array ARR. The source and the drain of the transistors Tr_{WL} can be connected. In this way, the capacitance effectively connected any given one of the word lines can be closely approached and an environment emulating, for the dummy word line, the environment of the word lines is reproduced.

The transistors Tr_{BL} and Tr_{WL} of the emulating circuits Emul.BL and Emul.WL preferably match in characteristics (geometry, dimension . . . ) the transistors of the bit cells BC of the array ARR, to better replicate the electrical environment of the bit lines and word lines.

More generally, the emulating circuits reproduce the RC characteristics of the bit lines and the word lines as seen by the memory circuit when charging the bit lines during a read operation.

In the present example, the bit line emulating circuit Emul.BL comprises a control transistor Tr_{Cnt}, that can be an NMOS transistor having one of a source and a drain connected to ground GND, the other of the source and the drain connected to the dummy bit line DBL, and a gate connected to the dummy word line DWL through the inverter INV. When the dummy word line is at a low voltage, the nmos control transistor Tr_{Cnt} connects the dummy bit line to ground, effectively permitting its discharge. When the dummy word line is at a high voltage, at least one of the pmos transistors Tr_{Adj} charge the dummy bit line to Vdd.

As illustrated by FIG. 3, the timing control circuit T-Cntl may comprise a reset signal generating circuit Reset-Gen, a pulse generating circuit Pulse-Gen and a pulse width determining circuit Pulse-Width and a delay circuit Del.

The timing control circuit T-Cntl has an input In1 to receive an external clock signal Ext-Clck, an input In2 to be connected to the dummy bit line DBL, and an output Out1 to output the internal clock signal Int-Clck towards the sense amplifier circuit S-Amp and other circuits that are function of the clock.

The reset signal generating circuit Reset-Gen, connected to the dummy bit line DBL through the input In2, is configured to generate and send a pulse reset signal Pulse-Reset when a voltage of the dummy first line reach a given threshold. This threshold can be predetermined and adjusted as conventionally known, for example by dimensions of a transistor and/or use of buffer circuits and such.

The reset signal generating circuit Reset-Gen can also be configured to connect the dummy bit line DBL to a line set at a voltage Vdd during a charging operation of the dummy bit line, for example when a trigger signal Stp-Trig sent through the dummy word line DWL is at a high logic level. The reset signal generating circuit Reset-Gen can also be configured to connect the dummy bit line DBC to the ground GND when the trigger signal Stp-Trig sent through the dummy word line DWL is at a low logic level. These function can be obtained by connecting the dummy word line to a gate of a transistor connecting, through its source and drain, the dummy bit line to a line itself either put at the Vdd voltage or connected to ground GND.

The pulse generating circuit Pulse-Gen has a third input In3 connected to the external clock input In1 and a fourth input In4 configured to receive the pulse reset signal Pulse-Reset through generated by the reset signal generating circuit Reset-Gen. The pulse generating circuit can be configured (i) to generate a trigger signal Stp-Trig in response to a pulse of the external clock signal to charge the dummy word line and (ii) to generate a pulse generating signal Pulse-Gen-Clck comprising a pulse beginning with the pulse of the external clock signal Ext-Clck and ending upon reception of the pulse reset signal Pulse-Reset. The trigger signal Stp-Trip and the pulse generating signal Pulse-Gen-Clck are output by the pulse generating circuit Pulse-Gen through second and third outputs Out2 and Out3, respectively.

The pulse width determining circuit Pulse-Width is configured to perform a function of a OR logical gate with the external clock signal Ext-Clck and the pulse generating signal Pulse-Gen-Clck as inputs and the internal clock signal Int-Clck as output. To this end, pulse width determining circuit Pulse-Width has a fifth input In5 connected to the third output Out3 and a sixth input In6 connected to the first input In1.

As illustrated by FIG. 4, the pulse width determining circuit Pulse-Width can consist in a OR logic gate input with the external clock signal Ext-Clck and the pulse generating signal Pulse-Gen-Clck, the output being the internal clock signal Int-Clck.

According to the interaction between the elements mentioned above, a pulse of the internal clock signal Int-Clck output by the pulse width determining circuit Pulse-Width begins with a rise of a pulse of the external clock signal and ends with the longest one of (i) a duration for the pulse of the external clock signal to end and (ii) a duration for the dummy bit line to be charged up to a predetermine threshold.

The delay circuit Del is only optional and can be inserted between the third output of the pulse generating circuit Pulse-Gen and the fifth input of the pulse width determining circuit Pulse-Width. The delay circuit Del comprises inputs (not illustrated) that can be used by the user to finely adjust delay

Still, the invention is not limited to the specific examples illustrated by FIGS. 3 to 7, and the functions of the individual circuits forming the timing control circuit can of course be implemented in a variety of ways.

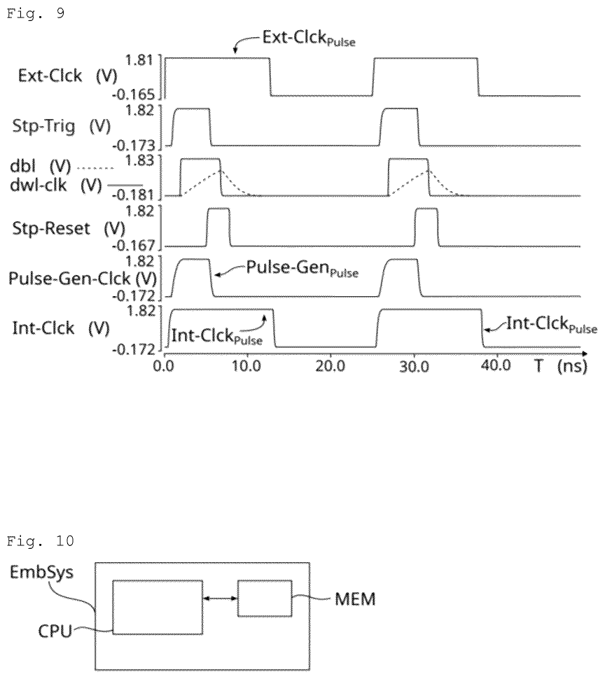

FIG. 8 and FIG. 9 are time charts illustrating the functioning of the time control circuit T-Cntl, that is able to take into account the effective charging time of a dummy bit line DBL, considered as representative of the charging time of the bit lines BL, to generate an internal clock signal Int-Clck. In the charts, voltages are expressed in volts V and time is expressed in nanoseconds ns. These charts are the results of simulations of the functioning of the circuit illustrated by FIGS. 3 to 7.

FIG. 8 illustrates the situation where the memory circuit MEM originates from a slow corner, which implies that the bit lines are likely not to be fully charged at the end of an external clock pulse that is supposed to control the charging time of the bit lines and the instant the sense amplifier circuit is enabled. In that case, without correction, the sense amplifier circuit may be disabled (sense amp sensing during high clock) too early to surely assess the logical level of a bit cell, that is evaluated through the bit line.

However, according to the invention, the time control circuit T-Cntl controls the length of a pulse of the internal clock signal to match the time it takes to charge the dummy bit line, so that the sense amplifier circuit is disabled automatically when the dummy bit line and thus a bit line of the array are sufficiently charged.

As illustrated by the time chart, when a pulse Ext-Clck_{Pulse} of the external clock signal Ext-Clck rises, the pulse generating circuit Pulse-Gen generates a pulse of the trigger signal Stp-Trig and a pulse Pulse-Gen_{Pulse} of the pulse generating signal Pulse-Gen-Clck. The pulse Ext-Clck_{Pulse} also initiates a pulse Int-Clck_{Pulse} of the internal clock signal Int-Clk.

Rise of the trigger signal Stp-Trig causes rising in the voltage dwl-clk of the dummy word line DWL, which is sent back to the time control circuit T-Cntl, more specifically to the reset signal generating circuit Reset-Gen.

Rise of the voltage dwl-clk of the dummy word line DWL causes rising in the voltage dbl of the dummy bit line DBL which allows tracking the time it takes for a bit line to charge.

When the voltage dbl of the dummy bit line reaches a given threshold, the reset signal generating circuit Reset-Gen generates a pulse in the pulse reset signal Pulse-Reset.

The pulse in the pulse reset signal Pulse-Reset triggers falling of the pulse of the pulse generating signal Pulse-Gen-Clck. At that time, since the pulse of the external clock signal is already terminated (we are in the hypothesis of slow corner, with the dummy bit line charging slower that the time it takes to a pulse of the external clock signal to end) and thus the external clock signal is low, only the pulse generating signal Pulse-Gen-Clck was keeping the internal clock signal Int-Clck high. Thus, it is the falling of the pulse of the pulse generating signal Pulse-Gen-Clck that triggers falling of the pulse of the internal clock signal Int-Clck and disables the sense amplifier circuit S-Amp.

In this situation, time control circuit T-Cntl has lengthened the pulse enabling the sense amplifier circuit, providing the required time for the dummy bit line and the bit line to be read, to be sufficiently charged.

FIG. 9 illustrates the situation where the memory circuit MEM originates from a fast corner, which implies that the bit lines are likely to be fully charged ahead of the end of an external clock pulse that controls the charging time of the bit lines and the instant the sense amplifier circuit is enabled.

As illustrated by the time chart, when a pulse Ext-Clck_{Pulse} of the external clock signal Ext-Clck rises, the pulse generating circuit Pulse-Gen generates a pulse of the trigger signal Stp-Trig and a pulse Pulse-Gen_{Pulse} of the pulse generating signal Pulse-Gen-Clck. The pulse Ext-Clck_{Pulse} also initiates a pulse Int-Clck_{Pulse} of the internal clock signal Int-Clk.

Rise of the trigger signal Stp-Trig causes rising in the voltage dwl-clk of the dummy word line DWL, which is sent back to the time control circuit T-Cntl, more specifically to the reset signal generating circuit Reset-Gen.

Rise of the voltage dwl-clk of the dummy word line DWL causes rising in the voltage dbl of the dummy bit line DBL, which allows tracking the time it takes for a bit line to charge.

When the voltage dbl of the dummy bit line reaches a given threshold, the reset signal generating circuit Reset-Gen generates a pulse in the pulse reset signal Pulse-Reset.

The pulse in the pulse reset signal Pulse-Reset triggers falling of the pulse of the pulse generating signal Pulse-Gen-Clck. At that time, since the pulse of the external clock signal is still high (we are in the hypothesis of fast corner, with the dummy bit line charging faster that the time it takes to a pulse of the external clock signal to end) and thus the external clock signal is high. Thus, it is the falling of the pulse of the external clock signal Ext-Clck that triggers falling of the pulse Int-Clck_{Pulse} of the internal clock signal Int-Clck and disables the sense amplifier circuit S-Amp.

In this situation, time control circuit T-Cntl let the external clock signal define the timing to enable the sense amplifier circuit S-Amp: the internal clock signal Int-Clck is substantially identical to the external signal clock signal Ext-Clck.

We see that the time control circuit according to the invention allows an automatic adaptation of the driving of the memory MEM, regardless of the exact characteristics of the memory with regards to the charging time of the bit lines and/or the word lines. More specifically, a pulse Int-Clck_{Pulse} of the internal clock signal Int-Clk has a width defined as a longest one of the lengths of (i) a pulse of the external clock signal Ext-Clck_{Pulse} and (ii) a pulses Pulse-Gen_{Pulse} of the pulse generating clock signal Pulse-Gen-Clk.

In this description, the memory arrays illustrated by FIG. 1(A) and FIG. 2 are considered as being arrays of resistive-type random access memories. However, the invention is not limited to this kind of memory. Other examples of memories to which the memory circuit according to the invention can be applied include static random access memories. In this case, the two lines connecting a column of bit cells BC to a multiplexer circuit SL/BL-Mux are often referred to as a bit line pair formed of a first bit line and a second bit line. It can also be said that the embodiments of the invention can concern memories in which data value stored by any given bit cell are determined by voltage of a corresponding single bit line signal, or memories using a pair of two bit lines to determine data stored by any given bit cell, the data value being determined by detecting a voltage differential between the two bit lines. More generally, any architecture can be employed for the array ARR of bit cells and for the bit cells BC.

Each of the examples mentioned in this document can be freely combined within technical limits understood by the practitioner in the field of the invention.

Other variations to the disclosed embodiment can be understood and effected by those skilled in the art in practicing the claimed invention, from a study of the drawings, the disclosure, and the appended claims.

1. A memory circuit comprising:
an array of bit cells arranged in rows of bit cells each connected to a respective word line and in columns of bit cells each connected to a respective one of bit lines, the word lines being connected to a word line driver circuit, the bit lines being connected to a multiplexer circuit;
a sense amplifier circuit configured to be connected to the bit lines,
an external clock input configured to be fed with an external clock signal comprising external clock pulses having a first length of time, and
a timing circuit configured to track a time taken to charge one of the bit lines and that is a second length of time,
the timing circuit being configured to generate an internal clock signal comprising internal clock pulses and transmit the internal clock signal to the sense amplifier circuit, the internal clock pulses having a width defined as a longest one of the first length of time and the second length of time.

2. The memory circuit according to claim 1, the memory circuit being configured to drive respective voltages of the bit lines in accordance to data stored in bit cells respectively connected to the bit lines during a read operation of the memory circuit.

3. The memory circuit according to claim 1, wherein the timing circuit is configured to track the time taken to charge one of the first lines by tracking a time taken to charge a dummy bit line and that is representative of the time taken to charge the bit lines.

4. The memory circuit according to claim 1 further comprising:
a dummy word line; and
a dummy first line;
the timing circuit comprising:
a reset signal generating circuit configured to generate and send a pulse reset signal when a voltage of the dummy first line reach a given threshold;
a pulse generating circuit having a first input connected to the external clock input and a second input configured to receive the pulse reset signal, the pulse generating circuit being configured (i) to generate and send a trigger signal to charge the dummy word line in response to a pulse of the external clock signal and (ii) to generate a pulse generating signal comprising a pulse beginning with the pulse of the external clock signal and ending upon reception of the pulse reset signal; and
a pulse width determining circuit configured to receive (i) the external clock signal and (ii) the pulse generating signal, the selecting circuit being further configured to generate and output the internal clock signal.

5. The memory circuit according to claim 4, the pulse width determining circuit being configured to perform a function of a OR logical gate with the external clock signal and the pulse generating signal as inputs and the internal clock signal as output.

6. The memory circuit according to claim 4, further comprising a dummy bit line emulating circuit connected to the dummy bit line and configured to emulate an environment of one of the bit lines of the array of bit cells so that charging the dummy bit line takes substantially a same amount of time as charging the one of the bit lines.

7. The memory circuit according to claim 4, further comprising a dummy word line emulating circuit connected to the dummy word line and configured to emulate an environment of one of the word lines of the array of bit cells so that a signal would propagate substantially identically along the dummy word line and along the one of the word lines.

8. The memory circuit according to claim 4, further comprising a delay circuit configured to delay the pulse generating signal generated by the pulse generation circuit before the pulse generating signal reaches the pulse width determining circuit.

9. The memory circuit according to claim 1, wherein the memory circuit is a resistive RAM.

10. An embedded system comprising:
a microprocessor
a memory circuit connected to the microprocessor, the memory circuit comprising:
an array of bit cells arranged in rows of bit cells each connected to a respective word line and in columns of bit cells each connected to a respective one of bit lines, the word lines being connected to a word line driver circuit, the bit lines being connected to a multiplexer circuit;
a sense amplifier circuit configured to be connected to the bit lines,
an external clock input configured to be fed with an external clock signal comprising external clock pulses having a first length of time, and
a timing circuit configured to track a time taken to charge one of the bit lines and that is a second length of time,
the timing circuit being configured to generate an internal clock signal comprising internal clock pulses and transmit the internal clock signal to the sense amplifier circuit, the internal clock pulses having a width defined as a longest one of the first length of time and the second length of time.

11. The embedded system according to claim 10, the memory circuit being configured to drive respective voltages of the bit lines in accordance to data stored in bit cells respectively connected to the bit lines during a read operation of the memory circuit.

12. The embedded system according to claim 10, wherein the timing circuit is configured to track the time taken to charge one of the first lines by tracking a time taken to charge a dummy bit line and that is representative of the time taken to charge the bit lines.

13. The embedded system according to claim 10 further comprising:
a dummy word line; and
a dummy first line;
the timing circuit comprising:
a reset signal generating circuit configured to generate and send a pulse reset signal when a voltage of the dummy first line reach a given threshold;
a pulse generating circuit having a first input connected to the external clock input and a second input configured to receive the pulse reset signal, the pulse generating circuit being configured (i) to generate and send a trigger signal to charge the dummy word line in response to a pulse of the external clock signal and (ii) to generate a pulse generating signal comprising a pulse beginning with the pulse of the external clock signal and ending upon reception of the pulse reset signal; and
a pulse width determining circuit configured to receive (i) the external clock signal and (ii) the pulse generating signal, the selecting circuit being further configured to generate and output the internal clock signal.

14. The embedded system according to claim 13, the pulse width determining circuit being configured to perform a function of a OR logical gate with the external clock signal and the pulse generating signal as inputs and the internal clock signal as output.

15. The embedded system according to claim 13, further comprising a dummy bit line emulating circuit connected to the dummy bit line and configured to emulate an environment of one of the bit lines of the array of bit cells so that charging the dummy bit line takes substantially a same amount of time as charging the one of the bit lines.

16. The embedded system according to claim 13, further comprising a dummy word line emulating circuit connected to the dummy word line and configured to emulate an environment of one of the word lines of the array of bit cells so that a signal would propagate substantially identically along the dummy word line and along the one of the word lines.

17. The embedded system according to claim 13, further comprising a delay circuit configured to delay the pulse generating signal generated by the pulse generation circuit before the pulse generating signal reaches the pulse width determining circuit.

18. The embedded system according to claim 10, wherein the memory circuit is a resistive RAM.
